(19) United States
(12) Patent Application Publication
(10) Pub. No.: US 2026/0112569 A1
(43) Pub. Date: Apr. 23, 2026

(54) PRECISE AUTOMATED CONTROL OF LAMELLA LIFT-OUT

(71) Applicant: FEI COMPANY, Hillsboro, OR (US)

(72) Inventors: Eva Štastná, Šardice (CZ); Branislav Straka, Brno (CZ); Iris Kico, Brno (CZ); Radek Smolka, Hillsboro, OR (US)

(21) Appl. No.: 18/924,691

(22) Filed: Oct. 23, 2024

(51) Int. Cl. H01J 37/20; H01J 37/28

(52) U.S. Cl. CPC H01J 37/20; H01J 37/28; H01J 2237/208

(57) ABSTRACT

A method of preparing a sample for electron microscopy imaging includes providing a substrate in an electron microscopy system comprising a probe for manipulating a freed sample of the substrate, applying a current flow between a stage of the system and the probe, detecting a first change in current flow in connection with contacting the sample with the probe, after detecting the first change in current flow, extracting the sample from the substrate with the probe, detecting a second change in current flow in connection with extracting the sample from the substrate, and confirming the sample is extracted from the substrate based at least in part on the second change in current flow.

### BACKGROUND

During manual and automated transmission electron microscopy (TEM) lamella preparation, the lift-out step is crucial for success of the process. In the manual use case, a user controls manipulation of a nanomanipulator in the surrounding of the lamella including changing the contrast when the nanomanipulator touches the lamella chunk. However, less experienced operators may fail to evaluate the situation, especially when preparing new types of samples. During automated processes, there is no feedback loop for confirming proper lamella preparation (e.g., there is no feedback loop for confirming proper lamella attachment to the nanomanipulator). Failures that occur during the attachment of the lamella chunk to the nanomanipulator needle are discovered later in the process, e.g., during welding.

### SUMMARY

According to one embodiment, a method of preparing a sample for electron microscopy imaging includes providing a substrate in an electron microscopy system comprising a probe for manipulating a freed sample of the substrate, applying a current flow between a stage of the system and the probe, detecting a first change in current flow in connection with contacting the sample with the probe, after detecting the first change in current flow, extracting the sample from the substrate with the probe, detecting a second change in current flow in connection with extracting the sample from the substrate, and confirming the sample is extracted from the substrate based at least in part on the second change in current flow.

The method may include various optional embodiments. The method may further include, in connection with confirming the sample is extracted from the substrate, using the probe, mounting the sample onto a sample carrier of the system, detecting a third change in current flow, and confirming the sample is mounted based at least in part on the third change in current flow. The method may further include, in connection with confirming the sample is mounted, detaching the probe from the sample, detecting a fourth change in current flow, and confirming the sample is detached from the probe based at least in part on a fourth change in current flow. A current level of the applied current flow may be between a base level and 1 mA. The first change in current flow may be a difference in the current level from the base level of the current flow to the current level of the applied current flow. The second change in current flow may be a difference in the current level of the applied current flow to the base level of the current flow. The method may further include logging conditions associated with the first change in current flow and the second change in current flow. The conditions may include one or more of pattern depth and pattern timing.

According to another embodiment, a system for preparing a sample for electron microscopy imaging includes an ion beam column, an electron beam column, a stage for supporting a substrate, a probe, a current source configured to provide a current that flows between the probe and the stage. and a controller for controlling operation of the system. The controller includes a memory storing computer instructions for detecting a current flow between the probe and the stage based on the probe contacting a sample of the substrate, using the ion beam to separate the sample from the substrate in connection with detecting the current flow, detecting a change in current flow in connection with extracting the sample from the substrate, and confirming the sample is extracted from the substrate based at least in part on the change in current flow.

The system may include various optional embodiments. A current level of the applied current flow may be between a base level and 1 mA. The change in current flow may be a difference in the current level from the base level of the current flow to the current level of the applied current flow. The instructions may further include logging conditions associated with the change in current flow. The conditions may include one or more of pattern depth and pattern timing.

According to yet another embodiment, a non-transitory computer-readable medium storing instructions executable by one or more processors of an electron microscopy system for causing the one or more processors to perform operations includes controlling a current flow to the system between a stage of the system and a probe of the system, detecting a first change in current flow in response to contact between a sample and the probe, in connection with detecting the first change in current flow, controlling extraction of the sample from a substrate with the probe, detecting a second change in current flow in connection with the extraction of the sample from the substrate, and confirming the sample is extracted from the substrate based at least in part on a second change in current flow.

The non-transitory computer-readable medium may include various optional embodiments. The instructions may include, in connection with confirming the sample is extracted from the substrate, controlling the probe for mounting the sample onto a surface of the system, detecting a third change in current flow, and confirming the sample is mounted based at least in part on the third change in current flow. A current level of the applied current flow may be between a base level and 1 mA. The first change in current flow may be a difference in the current level from the base level of the current flow to the current level of the applied current flow. The second change in current flow may be a difference in the current level of the applied current flow to the base level of the current flow. The instructions may further include logging conditions of the processing associated with first change in current flow and the second change in current flow. The conditions may include one or more of pattern depth and pattern timing.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram of an example dual beam system for preparing samples, according to various embodiments of the present disclosure.

FIG. 2 depicts a block diagram of an example computer system usable with systems and methods, according to various embodiments of the present disclosure.

FIG. 3A illustrates lamella extraction from a bulk sample, according to various embodiments of the present disclosure.

FIG. 3B illustrates lamella extraction from a bulk sample, according to various embodiments of the present disclosure.

FIG. 3C illustrates lamella extraction from a bulk sample, according to various embodiments of the present disclosure.

FIG. 4A illustrates lamella transfer to a lamella carrier, for example a transmission electron microscopy (TEM) grid, according to various embodiments of the present disclosure.

FIG. 4B illustrates lamella transfer to a lamella carrier, for example a transmission electron microscopy (TEM) grid, according to various embodiments of the present disclosure.

FIG. 4C illustrates lamella transfer to a lamella carrier, for example a transmission electron microscopy (TEM) grid, according to various embodiments of the present disclosure.

FIG. 5A illustrates lamella extraction from a bulk sample, according to various embodiments of the present disclosure.

FIG. 5B illustrates lamella extraction from a bulk sample, according to various embodiments of the present disclosure.

FIG. 5C illustrates lamella extraction from a bulk sample, according to various embodiments of the present disclosure.

FIG. 6A illustrates lamella transfer to a lamella carrier, for example a transmission electron microscopy (TEM) grid, according to various embodiments of the present disclosure.

FIG. 6B illustrates lamella transfer to a lamella carrier, for example a transmission electron microscopy (TEM) grid, according to various embodiments of the present disclosure.

FIG. 6C illustrates lamella transfer to a lamella carrier, for example a transmission electron microscopy (TEM) grid, according to various embodiments of the present disclosure.

FIG. 7 is a flowchart of a method of precisely controlling lamella lift-out and transfer, according to various embodiments of the present disclosure.

FIG. 8 is a flowchart of a computer-implemented method of precisely controlling lamella lift-out and transfer, according to various embodiments of the present disclosure.

### DETAILED DESCRIPTION

While exemplary embodiments have been illustrated and described, it will be appreciated that various changes can be made therein without departing from the spirit and scope of the disclosure.

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual beam charged particle microscope system, which typically includes a focused ion beam (FIB) and a SEM. Although much of the present disclosure discusses aspects with respect to a dual beam system, one having ordinary skill in the art would appreciate that any of the embodiments described herein may be applied to FIB systems, FIB-SEM systems, FIB-Laser systems, FIB-SEM-Laser systems, etc. During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

TEM lamella preparation may be performed via manual or automated processes. A user may manually control manipulation of a nanomanipulator in the surrounding of the lamella. However, less experienced operators may fail to evaluate the situation and make mistakes resulting in lift-out or transfer failures. Automated processes lack a feedback loop, and failures formed during lift-outs are not detectable until the lamella is removed. Earlier detection of failures would help operators to fine-tune process parameters in an efficient manner. Various embodiments of the present disclosure increase the robustness of the lift-out to 95%. In contrast, the success rate for a less experienced operator is nearly 86%. Said another way, embodiments of the present disclosure improve the success rate of the TEM lamella preparation by 10%. Various embodiments of the present disclosure provide improved control of the lift-out and grid welding steps during the TEM lamella preparation process for both manual and automated processes.

Between attachment and welding the lamella chunk onto the lamella carrier, for example a TEM grid, there are various steps that each take an average of 2 minutes to perform. Since throughput is as important as robustness, earlier detection of problems would save time and costs associated with TEM lamella preparation. In addition, any failure between attachment and welding will trigger the nanomanipulator needle cleaning to remove the chunk or any chunk residue. The nanomanipulator needle must be cleaned to prepare the nanomanipulator needle for the next lamella extraction. Needle cleaning can take up to tens of minutes or the whole needle needs to be exchanged, depending on the needle spike length and needle thickness. Reducing the need for needle cleaning will further reduce needle consumption and the time between needle exchanges.

Embodiments of the present disclosure provide contact detection between the nanomanipulator needle and the lamella that provides crucial information about the lift-out progress including whether there was a successful connection between the needle and the chunk in addition to the status of the following cut-out step of the lift-out process and whether the chunk was successfully welded onto the lamella carrier. This feedback provides both the manual user and the automated application the opportunity to make corrections and successfully complete the lift-out process.

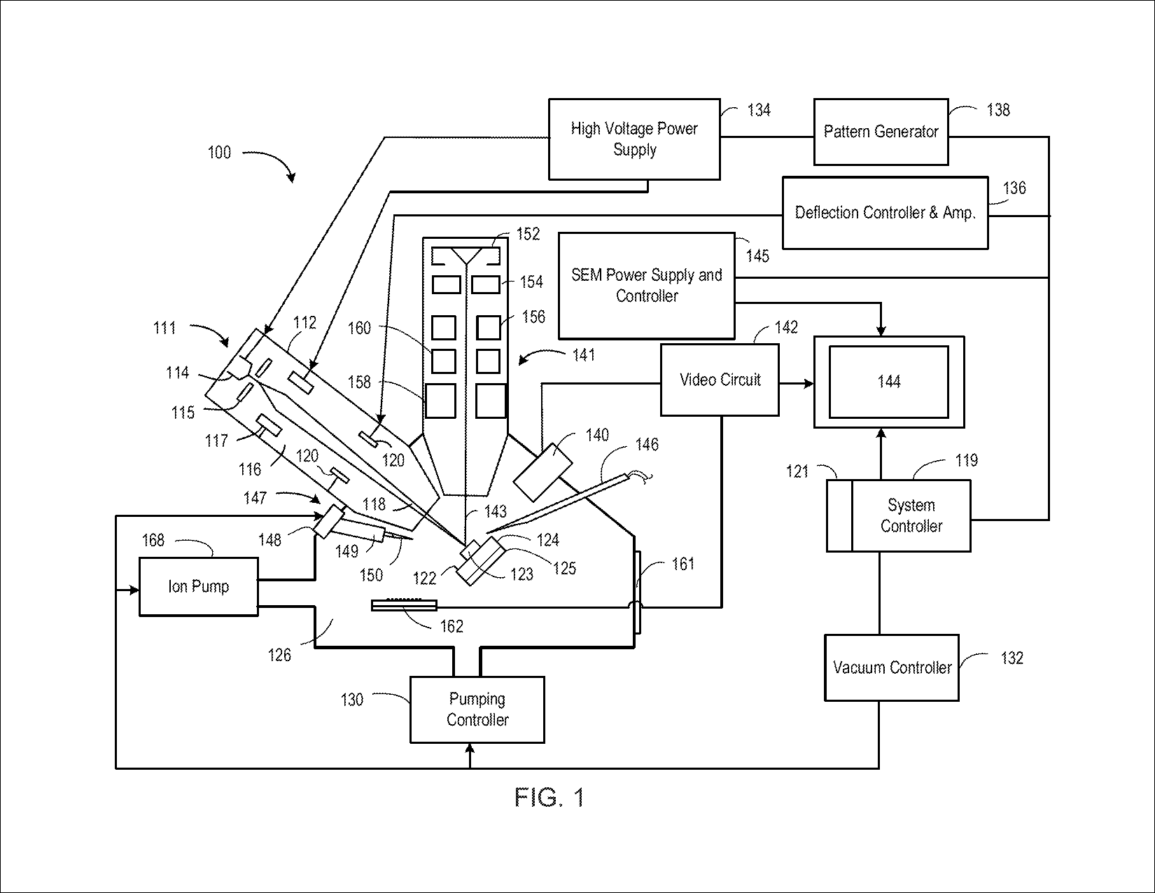

FIG. 1 is a schematic diagram of an example dual beam system 100, according to some embodiments. While an example of suitable hardware is provided below, the present disclosure is not limited to being implemented in any particular type of hardware. Various embodiments described herein may be implemented using one or more algorithms performed the computing system coupled to system 100.

An SEM 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto substrate 122, which is on stage 125 within lower chamber 126. Substrate 122 may be located on a surface of stage 125 or on lamella carrier 124, which extends from the surface of stage 125.

When the electrons in the electron beam strike substrate 122, secondary electrons are emitted. These secondary electrons are detected by secondary electron detector 140. In some embodiments, STEM detector 162, located beneath the lamella carrier 124 and the stage 125 collects electrons that are transmitted through the sample mounted on the TEM sample holder.

System 100 also includes FIB system 111 which includes an evacuated chamber having an ion column 112 within which are located an ion source 114 and focusing columns 116 including extractor electrodes and an electrostatic optical system. The axis of focusing column 116 may be tilted, 52 degrees for example, from the axis of the electron column 141. The ion column 112 includes an ion source 114, an extraction electrode 115, a focusing element 117, deflection elements 120, which operate in concert to form focused ion beam 118. Focused ion beam 118 passes from ion source 114 through focusing columns 116 and between electrostatic deflection means schematically indicated at 120 toward substrate 122, which may include, for example, a semiconductor wafer positioned on movable stage 125 within lower chamber 126. In some embodiments, a sample may be located on lamella carrier 124, where the sample may be a chunk extracted from substrate 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage can be used. Such a TEM sample stage will also preferably be moveable in the X, Y, and Z axes as well as tiltable and rotatable. In some embodiments, the tilting of the stage 125/lamella carrier 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting substrate 122 onto stage 125. Depending on the tilt of the stage 125/lamella carrier 124, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

The high voltage power supply provides an appropriate acceleration voltage to electrodes in focusing column 116 for energizing and focusing ion beam 118. When it strikes substrate 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing columns 116 for forming an approximately 1 keV to 60 keV ion beam 118 and directing the same toward a sample. Deflection controller and amplifier 136, operated in accordance with a prescribed pattern provided by pattern generator 138, is coupled to deflection elements 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at substrate 122 or lamella carrier 124 for either modifying the substrate 122 by ion milling, ion-induced etching, material deposition, or for the purpose of imaging the substrate 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may include precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward substrate 122. For example, iodine can be delivered to enhance etching, or a metal organic compound can be delivered to deposit a metal.

System controller 119 controls the operations of the various parts of dual beam system. Through system controller 119, a user can cause ion beam 118 or electron beam 143 to be scanned in a desired manner through commands entered into a conventional user interface (not shown). Alternatively, system controller 119 may control dual beam system in accordance with programmed instructions stored in a memory 121. In some embodiments, dual beam system incorporates image recognition software to automatically identify regions of interest, and then the system can manually or automatically extract samples in accordance with the present disclosure. For example, the system could automatically locate similar features on semiconductor wafers including multiple devices and take samples of those features on different (or the same) devices.

In operation in accordance with the techniques disclosed herein, system 100 images a working surface (e.g., a cutface) of a sample 123, the sample 123 being a chunk previously removed from a substrate. The chunk, which may be about 1 µm in thickness, may be attached to lamella carrier 124 in this example. As used herein, the working surface is a side surface of the chunk, the chunk needing to be thinned into a final lamella thickness. The sample 123 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 141 or the FIB 111.

Layers of sample 123 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 123 can be done by directing the FIB 111 toward a portion of the sample 123 in a pattern. For example, the ion beam may raster over the surface of the sample 123 in the portion, removing the desired layer. Embodiments of the present disclosure provide methods and systems for diverting an ion beam and removing the desired layer from the sample 123 using the diverted ion beam.

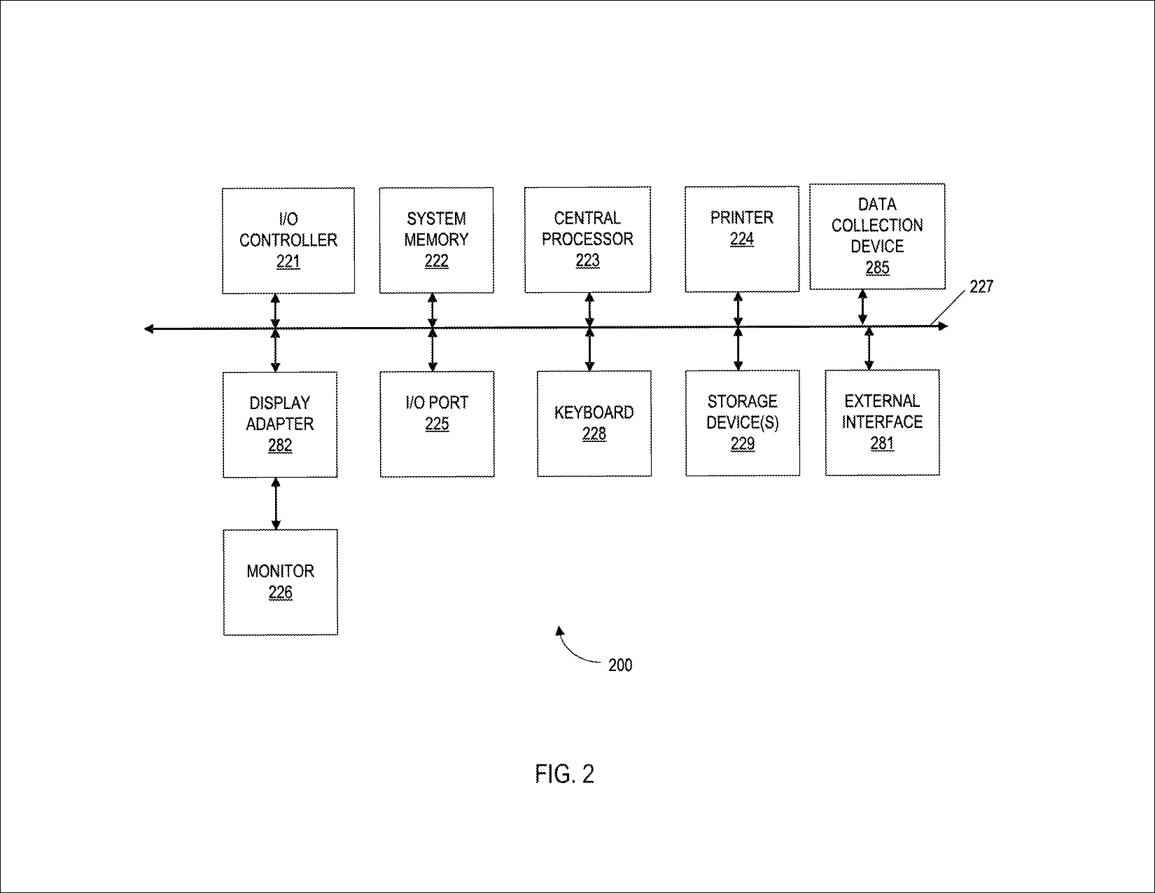

FIG. 2 depicts a block diagram of an example computer system usable with systems and methods according to embodiments of the present disclosure. Any of the computer systems mentioned herein may utilize any suitable number of subsystems. Examples of such subsystems are shown in FIG. 2 in computer system 200. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 2 are interconnected via a system bus 227. Additional subsystems such as a printer 224, keyboard 228, storage device(s) 229, monitor 226 (e.g., a display screen, such as an LED), which is coupled to display adapter 282, and others are shown. Peripherals and input/output (I/O) devices, which couple to I/O controller 221, can be connected to the computer system by any number of means known in the art such as input/output (I/O) port 225 (e.g., USB, FireWire^{®}). For example, I/O port 225 or external interface 281 (e.g., Ethernet, Wi-Fi, etc.) can be used to connect computer system 200 to a wide area network such as the Internet, a mouse input device, or a scanner. The interconnection via system bus 227 allows the central processor 223 to communicate with each subsystem and to control the execution of a plurality of instructions from system memory 222 or the storage device(s) 229 (e.g., a fixed disk, such as a hard drive, or optical disk), as well as the exchange of information between subsystems. The system memory 222 and/or the storage device(s) 229 may embody a computer readable medium. Another subsystem is a data collection device 285, such as a camera, microphone, accelerometer, and the like. Any of the data mentioned herein can be output from one component to another component and can be output to the user.

A computer system can include a plurality of the same components or subsystems, e.g., connected together by external interface 281, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

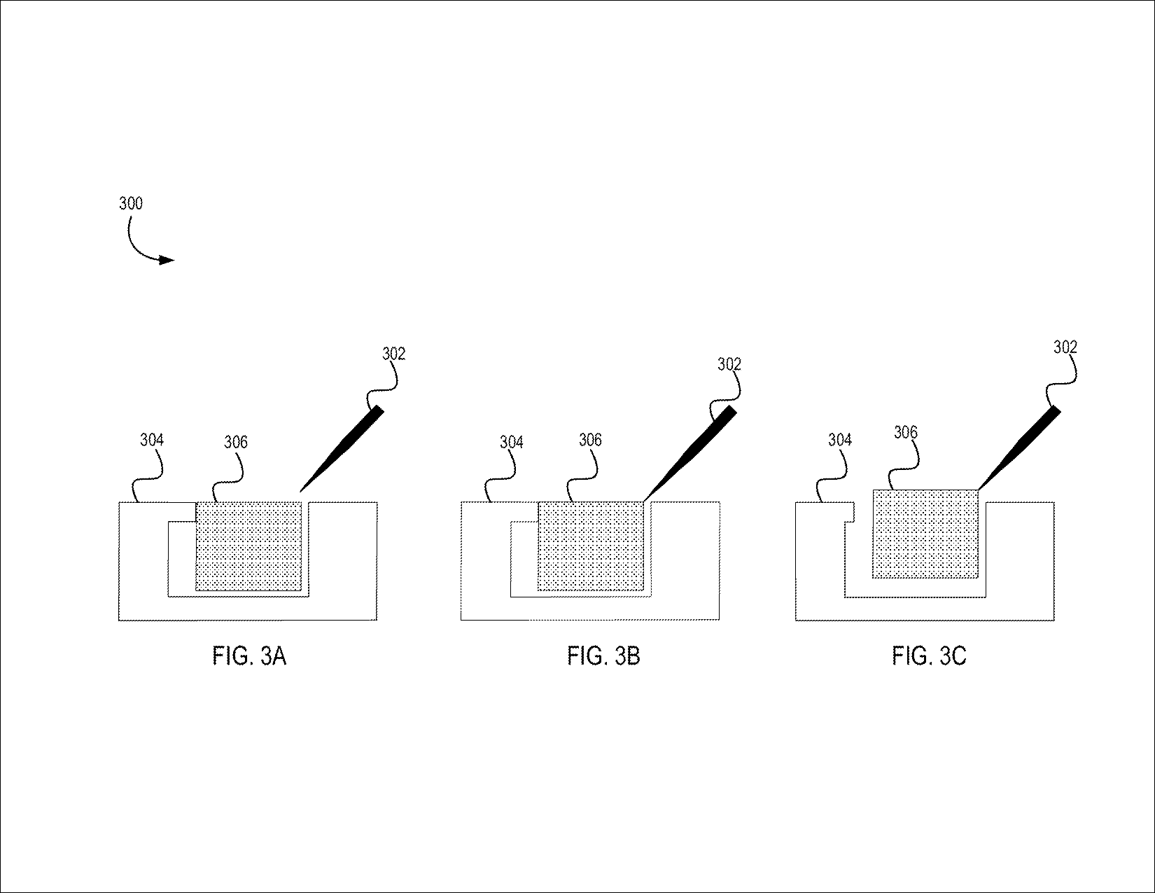

FIGS. 3A-3C illustrate lamella extraction from a bulk sample. FIGS. 3A-3C illustrate a TEM lamella preparation system 300 including a probe 302. A “probe” may be used interchangeably to refer to a nanomanipulator, needle, or the like. In at least some embodiments, the probe 302 may be a Thermo Fisher Scientific EasyLift nanomanipulator. The system 300 may further include a bulk sample 304 from which a lamella 306 is extracted. The lamella 306 may be milled from the bulk sample 304 using milling techniques known in the art. Accordingly, the probe 302 may be coupled to the lamella 306 for separating any remaining connection between the lamella 306 from the bulk sample 304, as would be appreciated by one having ordinary skill in the art. FIG. 3B illustrates the probe 302 contacting the lamella 306 and FIG. 3C illustrates the probe 302 separating or otherwise releasing the lamella 306 from the bulk sample 304 for transfer to another surface for further processing and/or imaging. Failures during the lift-out process may include unsuccessful welding of the lamella 306 to the probe 302 and/or insufficient cut-off of the lamella 306 from the bulk sample 304.

Lamella extraction as illustrated by FIGS. 3A-3C may be performed manually or via an automated system. Both techniques have risks that may result in unsuccessful lift-out of the sample. Manual lift-out has a high risk of the (unique) sample being lost by unexperienced operators who are less familiar with the parameters needed to successfully lift-out the sample. There are subjective criteria for evaluating the nanomanipulator’s position which is honed during extended operator experience. The success of manual lift-out processes depends on the experience of the operator. For automated systems, automated lift-out procedures are often completely dependent on image processing. Furthermore, there is a risk of unnecessary sample loss in the case of a false negative from the imaging processing system. Any error may result in the time-consuming process of needle cleaning.

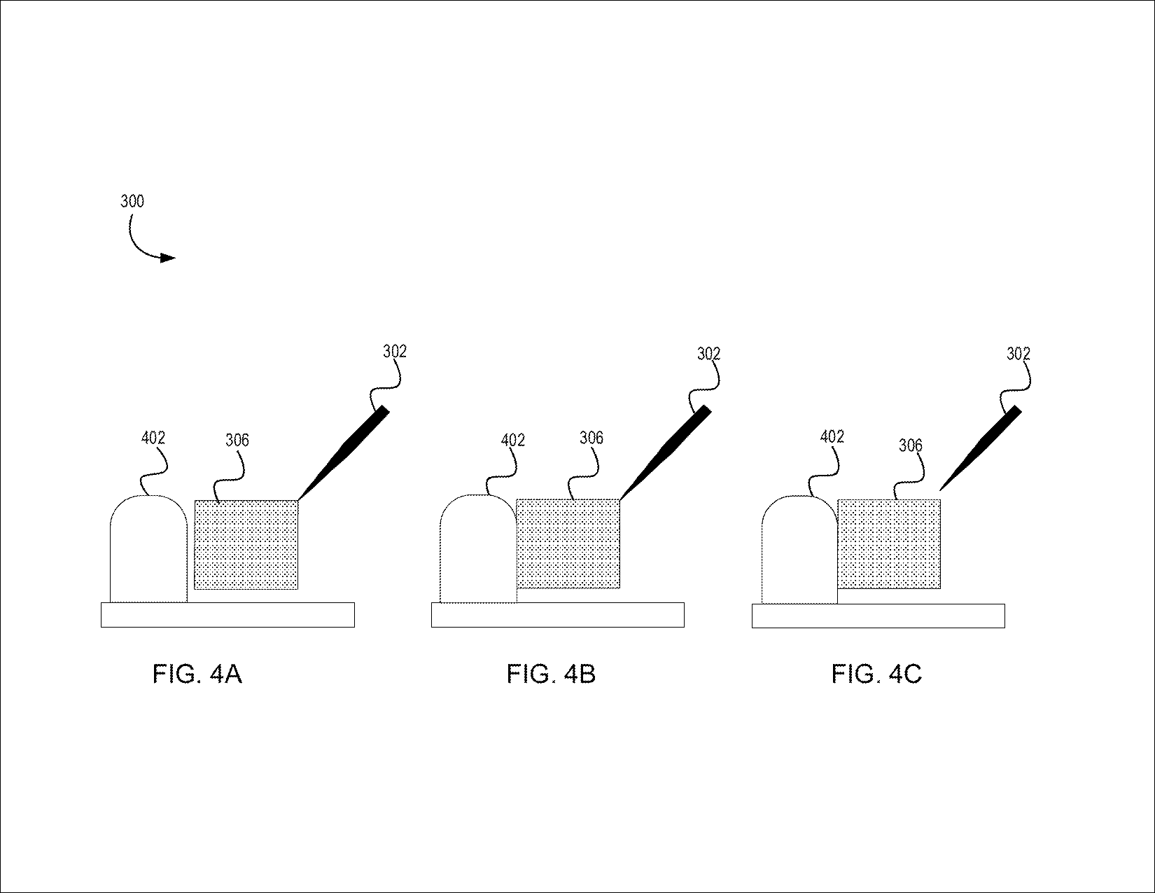

FIGS. 4A-4C illustrate lamella transfer to a lamella carrier. FIGS. 4A-4C illustrate the TEM lamella preparation system 300 including the probe 302 and the lamella 306 according to any of the embodiments described herein. FIG. 4A illustrates the probe 302 having the lamella 306 coupled thereto approaching a lamella carrier 402. The lamella 306 may be coupled to or otherwise attached to a sample holder, a stage, or any other surface for imaging or further processing. FIG. 4B illustrates the lamella 306 being welded or otherwise coupled to the lamella carrier 402. FIG. 4C illustrates the probe 302 being uncoupled from the lamella 306 after transfer. There are risks of unsuccessful welding of the lamella 306 to the lamella carrier 402 or insufficient cut-off of the lamella 306 from the probe 302 during the transfer process.

Various embodiments of the present disclosure utilize electric current for contact detection between a probe and a sample, between the sample and a sample carrier, etc. Contact detection and confirmation of contact between the probe and the sample (or the lamella carrier) provides reliable information that can be processed both by manual operators and influence automated systems to improve the performance of both techniques.

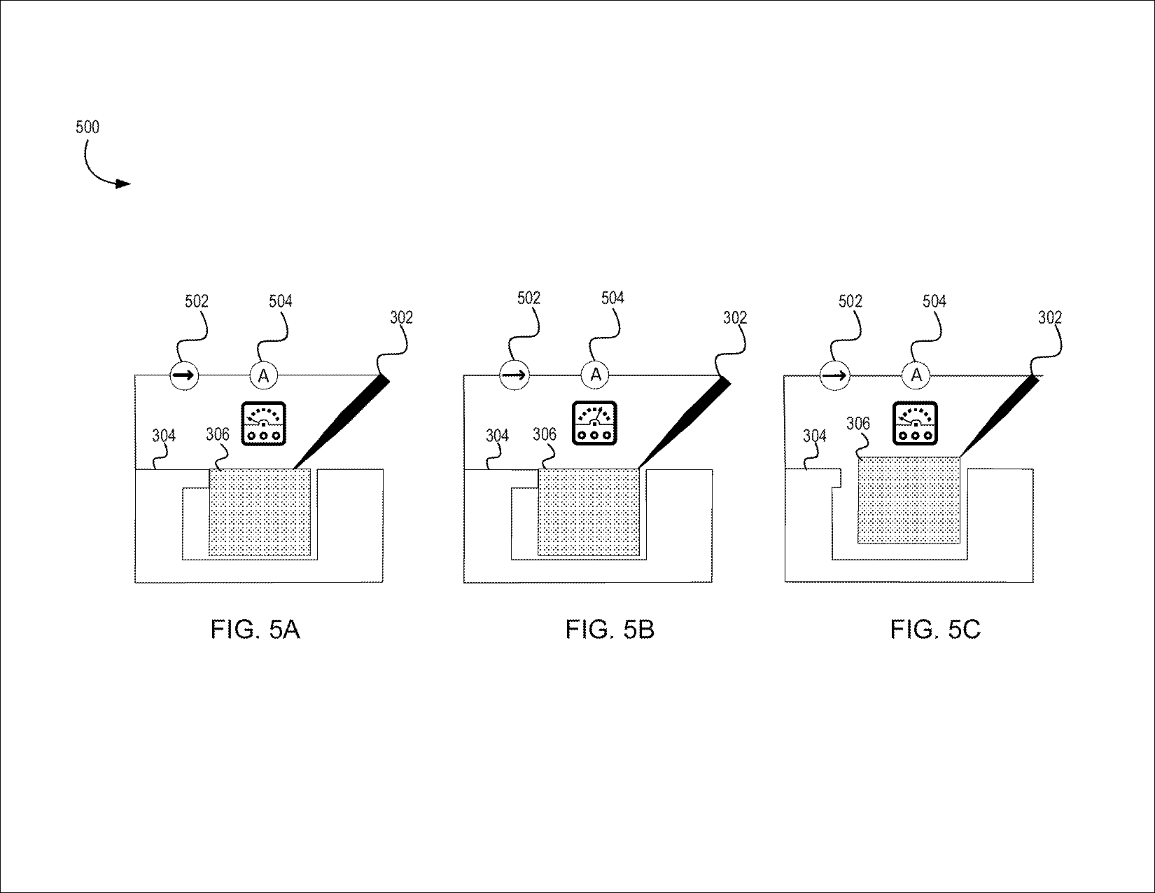

FIGS. 5A-5C illustrate lamella extraction from a bulk sample. FIGS. 5A-5C illustrate a TEM lamella preparation system 500 including a probe 302 as described with respect to other figures. The system 500 may further include a bulk sample 304 from which a lamella 306 is extracted. For example, the lamella 306 may be a unique sample that is milled from the bulk sample 304 that is to be removed for further evaluation and processing. FIG. 5A further illustrates the system 500 including a current source 502 for contact detection between the probe 302 and the lamella 306 according to embodiments of the present disclosure. An electric current source 502 may be incorporated in the system 500 between various embodiments for forming a current circuit. In some embodiments, the current source 502 may be incorporated between the lamella 306 and the probe 302. In other embodiments, the current source 502 may be incorporated between a stage supporting the sample, the bulk stage, a compustage (not shown), or the like, and the probe 302.

In at least some embodiments, the current source 502 includes a maximum current level which may be applied to the system 500. By monitoring the current flow through the current source 502, embodiments of the present disclosure provide effective detection of contact between the lamella 306 and the probe 302 and between the lamella 306 and a sample carrier, to be discussed in further detail below. Amperage readings may be output and used as input to other components of the system, such as a manipulation system, to direct further operation of the system. According to some embodiments, the system 500 may further include an ammeter 504 or the like, such as a multimeter, a specialized circuit, a picoammeter, a current probe, a clamp meter, etc., for measuring changes in current flow according to embodiments described herein. In at least some embodiments, a dedicated circuit may be implemented for measuring amperage. In exemplary embodiments, an existing system may include a component that measures amperage, and the component may be modified for further monitoring changes in current flow according to embodiments described herein.

As shown in FIG. 5A, the probe 302 is not in contact with the lamella 306 and the lamella 306 is coupled to the bulk sample 304. Accordingly, the current circuit is not complete and there is no current flowing between the probe 302 and the lamella 306. A current flow may be applied between a stage of the system 500 including the probe 302 and the lamella 306. The current flow may be a base current flow having a base current level greater than or equal to 1 pA. Said another way, when there is no electrical contact between the probe 302 and the lamella 306, the current flow is at a noise level of the measurement setup (e.g., about 1 pA).

FIG. 5B illustrates the probe 302 contacting the lamella 306 as the lamella 306 is coupled to the bulk sample 304. Contacting the lamella 306 with the probe 302 causes a first change in current flow that may be detected by the ammeter 504 or the like. The change in current flow may be indicative of a sufficient connection between the lamella 306 and the probe 302. For example, a current flow having a current value meeting or exceeding a predetermined value may be determined to be indicative of a sufficient connection between the lamella 306 and the probe 302 such that the lamella 306 is capable of being removed by the bulk sample 304 without unintended breakage or the like. After detecting the first change in current flow, the lamella 306 may be extracted from the bulk sample 304 with the probe 302 as shown in FIG. 5C. According to some embodiments, a second change in current flow may be detected in connection with the extraction of the lamella 306 from the bulk sample 304 as shown in FIG. 5C. The second change in current flow may be indicative of a successful detachment of the lamella 306 from the bulk sample 304. For example, a complete separation of the lamella 306 from the bulk sample 304 will break the circuit of the current flow and cause an interruption in the current flow and amperage detected by the system. Extraction of the lamella 306 from the bulk sample 304 may be confirmed based at least in part on the second change in current flow. Accordingly, embodiments of the present disclosure provide detection of electrical contact between the probe 302 and the lamella 306 at each step of the chunk lift-out. The detected current flow changes provide clear quantitative and qualitative information regarding the completeness of the contact and extraction for automation processes as well as for a manual user controlling a nanomanipulator or the like.

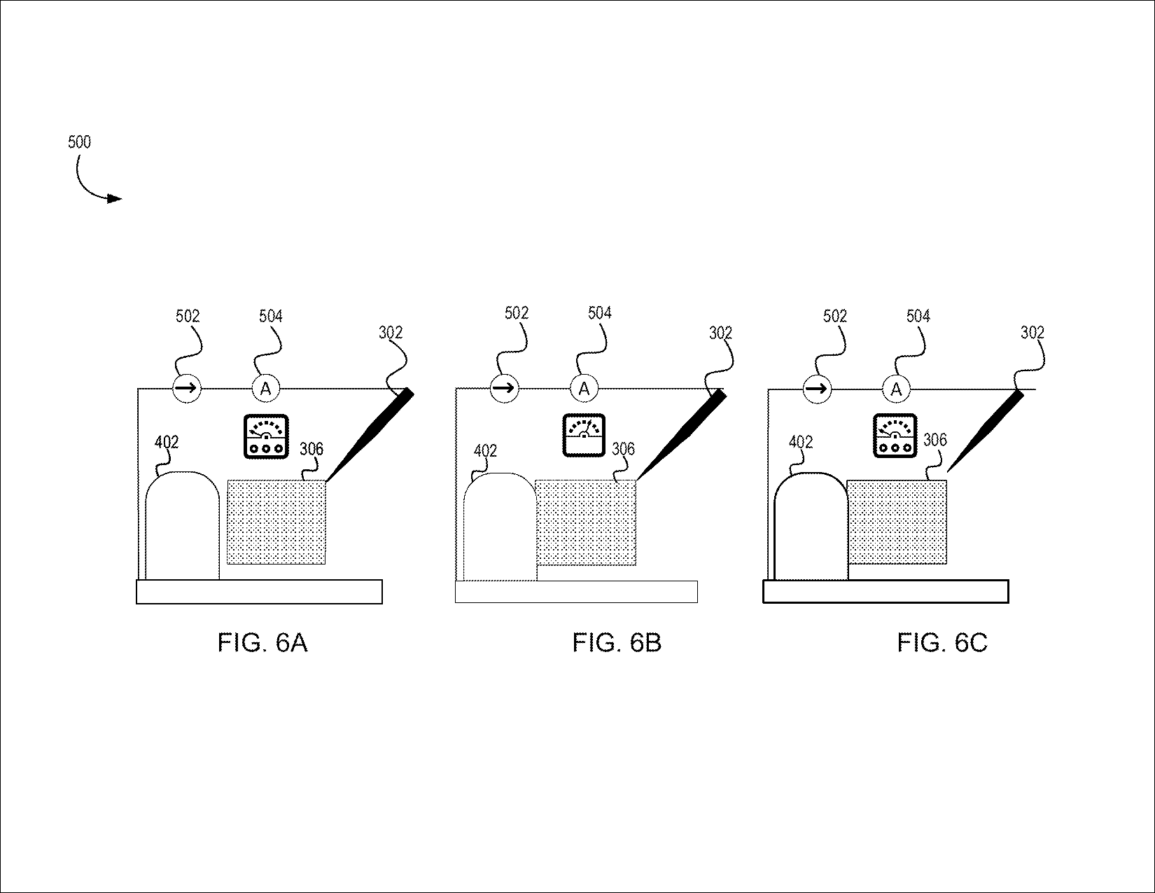

FIGS. 6A-6C illustrate lamella transfer to a lamella carrier. FIGS. 6A-6C illustrate the TEM lamella preparation system 500 including the probe 302 and the lamella 306 as described with respect to other figures. The system 500 further includes the current source 502 and may further include an ammeter 504 or other current measurement means known in the art such as a multimeter, a specialized circuit, a picoammeter, a current probe, a clamp meter, etc. In connection with confirming the lamella 306 is extracted from the bulk sample 304 (as shown in FIG. 5C), the probe 302 may be used to mount the lamella 306 onto a surface of the system 500, such as a lamella carrier 402. FIG. 6A illustrates the probe 302 having the lamella 306 coupled thereto approaching a lamella carrier 402.

FIG. 6B illustrates the lamella 306 being welded or otherwise coupled to the lamella carrier 402. The lamella 306 may be similarly coupled to a sample carrier or the like. A third change in current flow may be detected in response to the lamella 306 being mounted to the lamella carrier 402. The mounting may be confirmed based at least in part on the third change in current flow. For example, the increase in current flow (completing the current circuit) causes the third change in current flow.

FIG. 6C illustrates the probe 302 being uncoupled from the lamella 306 after transfer. After confirming the lamella 306 is mounted based at least part on the third change in current flow, the probe 302 may be detached from the lamella 306 as shown in FIG. 6C. A fourth change in current flow may be detected in response to the probe 302 detached from the lamella 306. The detachment of the probe 302 from the lamella 306 may be confirmed based at least in part on the fourth change in current flow. For example, the interruption of the current flow (breaking the current circuit) causes the fourth change in current flow.

According to various embodiments, any of the changes in current flow may be associated with a predetermined threshold. For example, a change in current flow may be the difference between a first current flow value and a second current flow value. A predetermined threshold may be defined for each of the differences. In response to determining a change in current flow is equal to or exceeds the predefined threshold, one or more of the current flow values and/or the determination may be output to a processor of the system or the like for proceeding to the next operation, as would be appreciated by one having ordinary skill in the art upon reading the present disclosure.

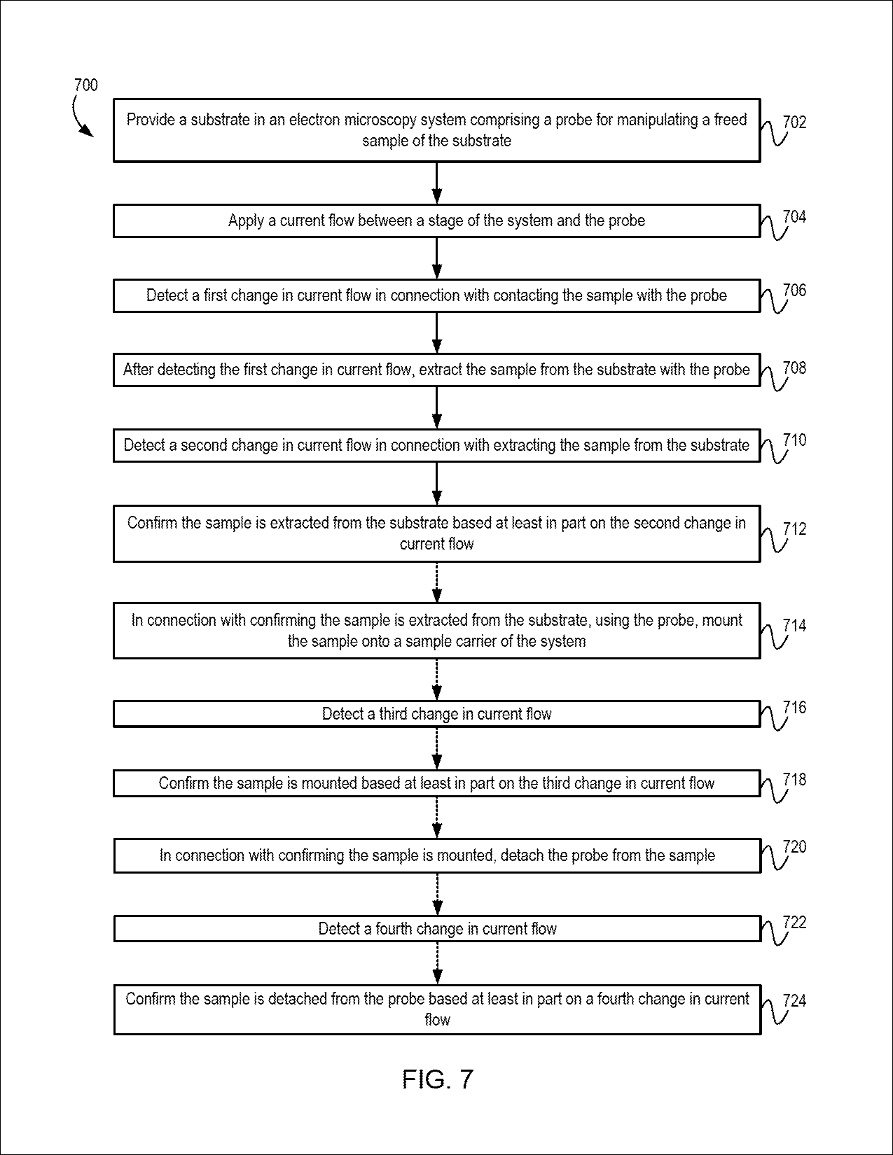

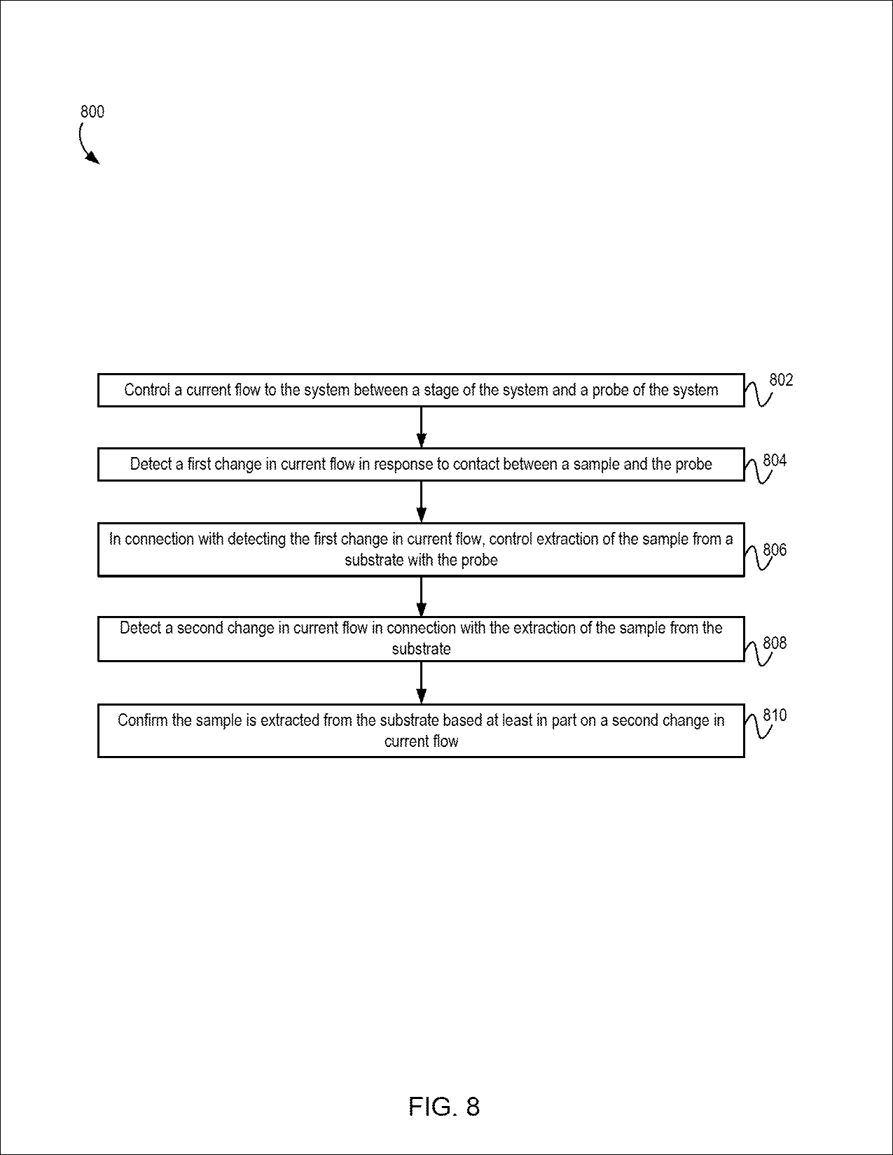

FIGS. 7 and 8 illustrate example flow diagrams showing processes 700 and 800, according to at least a few examples. These processes, and any other processes described herein, are illustrated as logical flow diagrams, each operation of which represents a sequence of operations that can be implemented in hardware, computer instructions, or a combination thereof. In the context of computer instructions, the operations may represent computer-executable instructions stored on one or more non-transitory computer-readable storage media that, when executed by one or more processors, perform the recited operations. Generally, computer-executable instructions include routines, programs, objects, components, data structures and the like that perform particular functions or implement particular data types. The order in which the operations are described is not intended to be construed as a limitation, and any number of the described operations can be combined in any order and/or in parallel to implement the processes.

Additionally, some, any, or all of the processes described herein may be performed under the control of one or more computer systems configured with specific executable instructions and may be implemented as code (e.g., executable instructions, one or more computer programs, or one or more applications) executing collectively on one or more processors, by hardware, or combinations thereof. As noted above, the code may be stored on a non-transitory computer readable storage medium, for example, in the form of a computer program including a plurality of instructions executable by one or more processors.

FIG. 7 is a flowchart of a method of precisely controlling lamella lift-out and transfer. Various embodiments of method 700, including any blocks described herein, may be performed manually or under the control of the computer system described in FIG. 2. Method 700 includes various operations for performing lamella lift-out and transfer according to embodiments of the present disclosure. Method 700 may include more or fewer operations than those described herein, and various operations may be performed in alternative configurations than those described herein. Method 700 may include block 702. Block 702 may include providing a substrate in an electron microscopy system including a probe for manipulating a freed sample of the substrate. The electron microscopy system may be a FIB-SEM system as described herein, according to at least some embodiments. In other embodiments, the system may be a FIB system, a FIB-SEM system, a FIB-Laser system, a FIB-SEM-Laser system, etc. The system may include any of the embodiments described herein in any combination. The probe may be used interchangeably to refer to a nanomanipulator, a needle, or the like. In at least some embodiments, the probe may be a Thermo Fisher Scientific EasyLift nanomanipulator.

Block 704 may include applying a current flow between a stage of the system and the probe. The current flow may be applied to a bulk sample through the stage of the system. The current flow may be a base current flow having a base current level greater than or equal to 1 pA. When there is no electrical contact between the probe and the sample, the current flow is at a noise level of the measurement setup (e.g., about 1 pA). According to some embodiments, the current level of the applied current flow is between a base level and 10 mA. In some embodiments, the current level of the applied current flow is between a base level and 10 µA. in yet further embodiments, current level of the applied current flow is between a base level and 100 nA.

Block 706 may include detecting a first change in current flow in connection with contacting the sample with the probe. The first change in current flow is a difference in the current level from the base level of the current flow to the current level of the applied current flow. According to various embodiments, block 706 may further include outputting information associated with the current flow in any suitable manner such that the current flow information may be used an input for a control system. For example, a current reading may be output at predetermined time intervals, e.g., such as every 5 seconds, every 10 seconds, every 15 seconds, etc., such that a control system may determine whether the current reading has changed by a predetermined threshold amount to cause a change to occur elsewhere in the system. For example, the control system may prompt initiation of block 708 in response to the input provided at block 706.

Block 708 may include, after detecting the first change in current flow (the probe is attached to the lamella), the last piece of material holding the lamella to the bulk sample may be removed, either by FIB or laser.

Block 710 may include detecting a second change in current flow in connection with extracting the sample from the substrate. The second change in current flow may be indicative of the disconnection between the sample and the substrate such that the current circuit is broken or otherwise interrupted. The second change in current flow is a difference in the current level of the applied current flow to the base level of the current flow. For example, the second change in current flow is the change from the applied current level (e.g., 1 mA) to a noise level of the current flow (e.g., 1 pA). The change in current information may be input to a processor of the system or the like for initiating other components of the system and/or initiation of block 712.

Block 712 may include confirming the sample is extracted from the substrate based at least in part on the second change in current flow. For example, if the sample is not fully extracted from the substrate, the current flow will not experience a change as the circuit of current flow is not broken. In some embodiments, if the sample is not sufficiently detached from the substrate, the current flow value may not change by a predetermined threshold amount. For example, there may be a change in the current flow value, but the change is not indicative of proper extraction of the sample from the substrate. In some embodiments, the extraction may be further confirmed based on imaging of the system or the like.

According to at least some embodiments, method 700 may include logging conditions associated with the first change in current flow and the second change in current flow. It would be advantageous to log the conditions of successful lift-outs and transfers for use in future processes. In some embodiments, the conditions may include a pattern size, a pattern shape, a pattern scanning strategy (e.g., a pattern type), a beam current, a beam energy, a pattern depth, a pattern timing, etc., or any combination thereof. This may be particularly useful for training operators performing manual lift-out operations. Accordingly, parameters of the lift-out process (and the transfer process) may be efficiently tuned and applied to future samples. Performing iterations of the process to determine the correct parameters for a sample may be avoided where the embodiments of the present disclosure provide real-time confirmation of parameters.

Method 700 may further include the transfer of the sample to a different surface of the system. For example, the sample may be transferred to a sample holder, a lamella carrier, or the like. Block 714 may include, in connection with confirming the sample is extracted from the substrate, using the probe to mount the sample onto a sample carrier of the system. The same probe may be used to transfer and mount the sample to the sample carrier, according to at least some embodiments. In other embodiments, the sample may be transferred to another prove prior to mounting.

Block 716 may further include detecting a third change in current flow. When the sample is mounted to the sample carrier, the circuit of the current flow is reinstated and the current level of the current flow changes again. For example, the third change in current flow is a difference in the current level from the base level of the current flow to the current level of the applied current flow. The current level may change from a noise level to the applied current level. In some embodiments, the current level of the applied current flow is less than or equal to 1 mA. In some embodiments, the sample is not determined to be properly mounted until the change in current flow value is equal to or greater than a predetermined threshold difference between an initial current flow value and a present current flow value. For example, mounting the sample may cause a change in the current flow value but a proper mounting or the complete mounting process may not be confirmed until a predetermined current flow value (or different in current flow values) is achieved, according to at least some embodiments.

Block 718 may further include confirming the sample is mounted based at least in part on the third change in current flow. The third change in current flow may be indicative of proper welding or attachment of the sample to the sample carrier. Confirming the sample is mounted may be further based on image processing or the like. Confirmation may be determined based at least in part on any of the embodiments described herein.

Block 720 may further include, in connection with confirming the sample is mounted, detaching the probe from the sample. The probe may be detached from the sample in a manner known in the art. The change in current flow may be indicative of the disconnection between the sample and the probe such that the current circuit is broken or otherwise interrupted. The change in current flow may be used at input for other components of the system to proceed to block 722, for example. In some embodiments, the change in current flow may be input into a manipulation system such that the manipulation system such that the probe is guided away from the sample as the sample is broken off or otherwise detached from the probe.

Block 722 may further include detecting a fourth change in current flow. When the sample is detached from the probe, the circuit of the current flow is broken and the current level of the current flow changes again. For example, the fourth change in current flow is a difference in the current level of the applied current flow to the current level of the base current flow. The current level may change from the applied current level to the noise level.

Block 724 may further include confirming the sample is detached from the probe based at least in part on a fourth change in current flow. The fourth change in current flow may be indicative of proper detachment of the sample from the probe. Confirming the sample is detached from the probe may be further based on image processing or the like.

FIG. 8 is a flowchart of a computer-implemented method of precisely controlling lamella lift-out and transfer. As recited above, each block of method 800 may represent a sequence of operations that can be implemented in hardware, computer instructions, or a combination thereof. Block 802 includes, for an electron microscopy system, controlling, by one or more processors of the system, a current flow to the system between a stage of the system and a probe of the system. Block 802 may include applying the current flow as described with respect to block 704 of method 700, as described in detail above.

Method 800 may further include block 804. Block 804 may include detecting a first change in current flow in response to contact between a sample and the probe. A current flow having a current value meeting or exceeding a predetermined value may be determined to be indicative of a sufficient connection between the sample and the probe. According to various embodiments, block 804 may further include outputting information associated with the current flow in any suitable manner such that the current flow information may be used an input for a control system. For example, a current reading may be output at predetermined time intervals, e.g., such as every 5 seconds, every 10 seconds, every 15 seconds, etc., such that a control system may determine whether the current reading has changed by a predetermined threshold amount to cause a change to occur elsewhere in the system.

Block 806 may include, in connection with detecting the first change in current flow, controlling extraction of the sample from a substrate with the probe. For example, in response to determining that the first change in current flow is a difference of a predetermined value, a manipulation system may be actuated to control the probe such that the sample is removed from the substrate. After detecting the first change in current flow (the probe is attached to the lamella), the last piece of material holding the lamella to the bulk sample may be removed, either by FIB or laser.

Block 808 may include detecting a second change in current flow in connection with the extraction of the sample from the substrate. The second change in current flow may be indicative of a successful detachment of the sample from the substrate. For example, a complete separation of the sample from the substrate will break the circuit of the current flow and cause an interruption in the current flow and amperage detected by the system.

Block 810 may include confirming the sample is extracted from the substrate based at least in part on a second change in current flow. For example, the decrease in current flow (interrupting the current circuit) causes the second change in current flow. Accordingly, the detected current flow changes provide clear quantitative and qualitative information regarding the completeness of the contact and extraction for automation processes of the system.

Various embodiments of the present disclosure provide precise control of the nanomanipulator-lamella connection, the lamella extraction from the bulk sample, the lamella-grid connection, the lamella cut-off from the nanomanipulator, etc. The contact detection provided by embodiments of the present disclosure increase the robustness of the system by providing precise control of each lift-out step. Additionally, embodiments of the present disclosure increase throughput of the system by enabling adjustment of pattern depth according to the measured current value and thereby providing faster tuning of automated jobs. For example, less iterations are required for new lamella types or different samples to determine proper condition parameters for the lift-out and transfer processes.

According to at least some embodiments, a system set-up as described herein may include a DualBeams system with 110 mm or 150 mm and a 6-inch stage. The system may include any 5-axis (e.g., X, Y, Z, rotation, tilt) stage with any type of motor (e.g., piezo or step engines). A change of 12 nA in current flow may be reliably and repeated detected for various steps of the process. Set-ups with all types of stages and holders may be implemented as would be appreciated by one having ordinary skill in the art.

Detection of electrical contact provides clear information about the connection between the nanomanipulator and the TEM lamella at all TEM lamella lift-out steps. This real-time information results in higher success rates of manual TEM lamella preparation procedures, accelerated training of new operators, higher time-efficiency of the TEM prep jobs (e.g., tuning of the pattern depths based on the current flow measurements), higher success rate of automated TEM prep jobs, more reliable and time efficient needle management between automated TEM prep jobs, and faster workflow tuning of the automated TEM prep jobs.

A further benefit of the embodiments described herein is the lift-out control provides information for investigation of a potentially failed automated job. For example, the information about the contact detection may help to identify the lift-out phase when the error occurred.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C#, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed but could have additional blocks not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the blocks. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the blocks of any of the methods described herein, potentially with different components performing a respective block or a respective group of blocks. Although presented as numbered blocks, blocks of methods herein can be performed at a same time or at different times or in a different order. Additionally, portions of these blocks may be used with portions of other blocks from other methods. Also, all or portions of a block may be optional. Additionally, any of the blocks of any of the methods can be performed with modules, units, circuits, or other means of a system for performing these blocks.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as "bottom" or "top" and the like can be used to describe an element and/or feature's relationship to other element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a "bottom" surface can then be oriented "above" other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter is not limited to the particular examples disclosed, but that such claimed subject matter may also include all aspects falling within the scope of appended claims, and equivalents thereof.

What is claimed is:

1. A method of preparing a sample for electron microscopy imaging comprising:
providing a substrate in an electron microscopy system comprising a probe for manipulating a freed sample of the substrate;
applying a current flow between a stage of the system and the probe;
detecting a first change in current flow in connection with contacting the sample with the probe;
after detecting the first change in current flow, extracting the sample from the substrate with the probe;
detecting a second change in current flow in connection with extracting the sample from the substrate; and
confirming the sample is extracted from the substrate based at least in part on the second change in current flow.

2. The method of claim 1, further comprising:
in connection with confirming the sample is extracted from the substrate, using the probe, mounting the sample onto a sample carrier of the system;
detecting a third change in current flow; and
confirming the sample is mounted based at least in part on the third change in current flow.

3. The method of claim 2, further comprising:
in connection with confirming the sample is mounted, detaching the probe from the sample;
detecting a fourth change in current flow; and
confirming the sample is detached from the probe based at least in part on a fourth change in current flow.

4. The method of claim 1, wherein a current level of the applied current flow is between a base level and 1 mA.

5. The method of claim 4, wherein the first change in current flow is a difference in the current level from the base level of the current flow to the current level of the applied current flow.

6. The method of claim 4, wherein the second change in current flow is a difference in the current level of the applied current flow to the base level of the current flow.

7. The method of claim 1, further comprising:
logging conditions associated with the first change in current flow and the second change in current flow.

8. The method of claim 7, wherein the conditions comprise one or more of pattern depth and pattern timing.

9. A system for preparing a sample for electron microscopy imaging comprising:
an ion beam column;
an electron beam column;
a stage for supporting a substrate;
a probe;
a current source configured to provide a current that flows between the probe and the stage; and
a controller for controlling operation of the system, the controller including a memory storing computer instructions for:
detecting a current flow between the probe and the stage based on the probe contacting a sample of the substrate;
using the ion beam to separate the sample from the substrate in connection with detecting the current flow;
detecting a change in current flow in connection with extracting the sample from the substrate; and
confirming the sample is extracted from the substrate based at least in part on the change in current flow.

10. The system of claim 9, wherein a current level of the applied current flow is between a base level and 1 mA.

11. The system of claim 10, wherein the change in current flow is a difference in the current level from the base level of the current flow to the current level of the applied current flow.

12. The system of claim 9, further comprising instructions for:
logging conditions associated with the change in current flow.

13. The system of claim 12, wherein the conditions comprise one or more of pattern depth and pattern timing.

14. A non-transitory computer-readable medium storing instructions executable by one or more processors of an electron microscopy system for causing the one or more processors to perform operations comprising:
controlling a current flow to the system between a stage of the system and a probe of the system;
detecting a first change in current flow in response to contact between a sample and the probe;
in connection with detecting the first change in current flow, controlling extraction of the sample from a substrate with the probe;
detecting a second change in current flow in connection with the extraction of the sample from the substrate; and
confirming the sample is extracted from the substrate based at least in part on a second change in current flow.

15. The non-transitory computer-readable medium of claim 14, further comprising instructions for:
in connection with confirming the sample is extracted from the substrate, controlling the probe for mounting the sample onto a surface of the system;
detecting a third change in current flow; and
confirming the sample is mounted based at least in part on the third change in current flow.

16. The non-transitory computer-readable medium of claim 14, wherein a current level of the applied current flow is between a base level and 1 mA.

17. The non-transitory computer-readable medium of claim 16, wherein the first change in current flow is a difference in the current level from the base level of the current flow to the current level of the applied current flow.

18. The non-transitory computer-readable medium of claim 16, wherein the second change in current flow is a difference in the current level of the applied current flow to the base level of the current flow.

19. The non-transitory computer-readable medium of claim 16, further comprising instructions for:
logging conditions of the processing associated with first change in current flow and the second change in current flow.

20. The non-transitory computer-readable medium of claim 19, wherein the conditions comprise one or more of pattern depth and pattern timing.
